(19) United States
(12) Patent Application Publication
(10) Pub. No.: US 2021/0343980 A1
(43) Pub. Date: Nov. 4, 2021

(54) METHOD FOR MANUFACTURING ENCAPSULATION STRUCTURE OF ORGANIC LIGHT EMITTING DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventors: Wenliang GONG, Wuhan (CN); Jiangjiang JIN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/336,943

(22) PCT Filed: Jan. 15, 2019
(86) PCT No.: PCT/CN2019/071731

§ 371 Date: Mar. 27, 2019

(30) Foreign Application Priority Data
Dec. 20, 2018 (CN) 201811562169.0

(51) Int. Cl. H01L 51/52; H01L 27/32; H01L 51/56

(52) U.S. Cl. CPC H01L 51/5253; H01L 51/56; H01L 27/322; H01L 27/3211

(57) ABSTRACT

A method for manufacturing an encapsulation structure of an organic light emitting display device is provided and includes the following steps: providing an organic light emitting portion; forming a first encapsulation layer on the organic light emitting portion, wherein the first encapsulation layer includes red, green, and blue subpixel regions, respectively corresponding to red, green, and blue subpixels of the organic light emitting portion; forming red, green, and blue color filters respectively in the red, green, and blue subpixel regions by inkjet printing; forming a planarization layer, a second encapsulation layer, and a light shielding layer on the first encapsulation layer, and the red, green, and blue color filters, wherein the light shielding layer includes polyimide; and etching the light shielding layer to form a plurality of holes, wherein the holes correspond to positions of the red, green, and blue subpixel regions.

### FIELD OF INVENTION

The present invention relates to a technical field in displays, and particularly to a method for manufacturing an encapsulation structure of an organic light emitting display device, and an encapsulation structure and an organic light emitting display device manufactured by the method.

### BACKGROUND OF DISCLOSURE

Referring to FIG. 1, which is a schematic cross-sectional view of an existing organic light emitting display device, having a polarizer 30. The organic light emitting display device includes an organic light emitting portion 10 having red subpixels 11, green subpixels 12, and blue subpixels 13. An encapsulation layer 20 and a polarizer 30 are formed on the organic light emitting portion 10. The polarizer 30 effectively reduces reflectivity of the panel under strong light, but loses nearly 58% of light output (e.g. the light output rate is about 42%), which is greatly adverse to a lifespan of an organic light emitting diode (OLED) panel. Moreover, the polarizer is thick (about 60 μm), the material thereof is fragile, and the polarizer is unfavorable for development of dynamic bendable products. In order to develop a bendable product based upon OLED technology, it is necessary to introduce new materials, new technologies, and new processes to replace the polarizer 30.

Referring to FIG. 2, which is a schematic cross-sectional view of an existing organic light emitting display device having a color filter layer 60. The organic light emitting display device includes an organic light emitting portion 40 having red subpixels 41, green subpixels 42, and blue subpixels 43. An encapsulation layer 50 and a color filter layer 60 are formed on the organic light emitting portion 40. Using a color filter layer 60 to replace a polarizer 30 is classified as a polarizer-less (POL-less) technique, which not only reduces the thickness of the encapsulation layer from about 60 μm to <5 μm. Moreover, the light output rate is increased from 42% to 60%. However, compared with the polarizer, the color filter layer has a higher surface reflectivity and a lower contrast under strong light, which is disadvantageous for outdoor display. The color filter layer 60 is composed of red filters 61, green filters 62, blue filters 63, and a light shielding layer 64 (also referred to as a black matrix). In the OLED panel, the red color filters 61, the green color filters 62, and the blue color filters 63 respectively have red color resists, green color resists, and blue color resists, which are respectively responsible for the light output of the corresponding red subpixels 61, green subpixels 62 and blue subpixels 63. The light shielding layer 64 is mainly responsible for preventing light leakage of the panel and reducing reflection of the panel.

However, photolithography, employing three photomasks, must be used in manufacturing processes for existing color filter layers, and the manufacturing processes are complicated. Moreover, the development and baking processes in the photolithography may damage functional layers in OLED panels. In addition, existing light shielding layers have poor bending endurance, so it is necessary to develop a method for manufacturing an encapsulation structure of an organic light emitting display device, which can simplify and improve the manufacturing processes for the color filter layer and enhance the bending endurance thereof.

### SUMMARY OF INVENTION

### Technical Problems

The object of the present disclosure is to provide a method for manufacturing an encapsulation structure of an organic light emitting display device, which can simplify the manufacturing process for the encapsulation structure of the organic light emitting display device, reduce damage caused by the manufacturing process to functional layers in organic light emitting diode (OLED) panels, and enhance the bending endurance thereof.

### Technical Solutions

In order to solve the above technical problems, the present disclosure provides a method for manufacturing an encapsulation structure of an organic light emitting display device, including:

a step S10 of providing an organic light emitting portion, wherein the organic light emitting portion includes a red subpixel, a green subpixel, and a blue subpixel;

a step of S20 of forming a first encapsulation layer on the organic light emitting portion, wherein the first encapsulation layer includes a red subpixel region, a green subpixel region, and a blue subpixel region, respectively corresponding to the red subpixel, the green subpixel, and the blue subpixel of the organic light emitting portion;

a step S30 of forming a red color filter, a green color filter, and a blue color filter respectively in the red subpixel region, the green subpixel region, and the blue subpixel region of the first encapsulation layer by inkjet printing;

a step S40 of irradiating the red color filter, the green color filter, and the blue color filter with ultraviolet light to cure the red color filter, the green color filter, and the blue color filter;

a step S50 of forming a planarization layer on the first encapsulation layer, the red color filter, the green color filter, and the blue color filter;

a step S60 of forming a second encapsulation layer on the planarization layer;

a step S70 of coating a light shielding layer on the second encapsulation layer, wherein the light shielding layer includes polyimide; and

a step S80 of etching the light shielding layer to form a plurality of holes, wherein the holes correspond to positions of the red subpixel region, the green subpixel region, and the blue subpixel region by photolithography.

In accordance with a further feature of an embodiment of the present disclosure, material of the first encapsulation layer and the second encapsulation layer is SiN.

In accordance with a further feature of an embodiment of the present disclosure, the step S20 includes a step of forming the first encapsulation layer on the organic light emitting portion by chemical vapor deposition; and the step 60 includes a step of forming the second encapsulation layer on the planarization layer by chemical vapor deposition.

In accordance with a further feature of an embodiment of the present disclosure, the step S50 includes a step of forming a transparent planarization layer on the first encapsulation layer, the red color filter, the green color filter, and the blue color filter by inkjet printing.

The present disclosure also provides an organic light emitting display device. An encapsulation structure of the organic light emitting display device is manufactured by the above method. The organic light emitting display device includes:

an organic light emitting portion including a red subpixel, a green subpixel, and a blue subpixel;

an encapsulation structure disposed to cover the organic light emitting portion, and including:

a first encapsulation layer disposed on the organic light emitting portion, and including a red subpixel region, a green subpixel region, and a blue subpixel region, respectively corresponding to the red subpixel, the green subpixel, and the blue subpixel of the organic light emitting portion;

a red color filter, a green color filter, and a blue color filter respectively formed in the red subpixel region, the green subpixel region, and the blue subpixel region of the first encapsulation layer;

a planarization layer disposed on the first encapsulation layer, the red color filter, the green color filter, and the blue color filter;

a second encapsulation layer disposed on the planarization layer;

a light shielding layer disposed on the second encapsulation layer; wherein the light shielding layer includes a polyimide, and a plurality of holes are defined on positions of the red subpixel region, the green subpixel region, and the blue subpixel region in the light shielding layer.

In accordance with a further feature of an embodiment of the present disclosure, material of the first encapsulation layer and the second encapsulation layer is SiN.

The present disclosure also provides an encapsulation structure for an organic light emitting display device. An organic light emitting portion of the organic light emitting display device includes a red subpixel, a green subpixel, and a blue subpixel. The encapsulation structure is manufactured by the above method, is disposed to cover the organic light emitting portion, and includes:

a first encapsulation layer disposed on the organic light emitting portion, and including a red subpixel region, a green subpixel region, and a blue subpixel region, respectively corresponding to the red subpixel, the green subpixel, and the blue subpixel of the organic light emitting portion;

a red color filter, a green color filter, and a blue color filter respectively formed in the red subpixel region, the green subpixel region, and the blue subpixel region of the first encapsulation layer;

a planarization layer disposed on the first encapsulation layer, the red color filter, the green color filters, and the blue color filter;

a second encapsulation layer disposed on the planarization layer;

a light shielding layer disposed on the second encapsulation layer; wherein the light shielding layer includes a polyimide, and a plurality of holes are defined on positions of the red subpixel regions, the green subpixel region, and the blue subpixel region in the light shielding layer.

In accordance with a further feature of an embodiment of the present disclosure, material of the first encapsulation layer and the second encapsulation layer is SiN.

In order to solve the above technical problems, the present disclosure provides a method for manufacturing an encapsulation structure of an organic light emitting display device, including:

a step S10 of providing an organic light emitting portion, wherein the organic light emitting portion includes a red subpixel, a green subpixel, and a blue subpixel;

a step of S20 of forming a first encapsulation layer on the organic light emitting portion, wherein the first encapsulation layer includes a red subpixel region, a green subpixel region, and a blue subpixel region, respectively corresponding to the red subpixel, the green subpixel, and the blue subpixel of the organic light emitting portion;

a step S30 of forming red color filter, green color filter, and blue color filter respectively in the red subpixel region, the green subpixel region, and the blue subpixel region of the first encapsulation layer by inkjet printing;

a step S40 of irradiating the red color filter, the green color filter, and the blue color filter with ultraviolet light to cure the red color filter, the green color filter, and the blue color filter;

a step S50 of forming a planarization layer on the first encapsulation layer, the red color filter, the green color filter, and the blue color filter by inkjet printing;

a step S60 of forming a second encapsulation layer on the planarization layer;

a step S70 of coating a light shielding layer on the second encapsulation layer, wherein the light shielding layer includes polyimide; and

a step S80 of etching the light shielding layer to form a plurality of holes, wherein the holes correspond to positions of the red subpixel region, the green subpixel region, and the blue subpixel region by photolithography.

In accordance with a further feature of an embodiment of the present disclosure, material of the first encapsulation layer and the second encapsulation layer is SiN.

In accordance with a further feature of an embodiment of the present disclosure, the step S20 includes a step of forming the first encapsulation layer on the organic light emitting portion by chemical vapor deposition; the step 60 includes a step of forming the second encapsulation layer on the planarization layer by chemical vapor deposition.

### Beneficial Effects

In the method for manufacturing the encapsulation structure of the organic light emitting display device, and the encapsulation structure and the organic light emitting display device manufactured by the method of the present disclosure, using inkjet printing, red, green, and blue color resists precisely cover the red, green, and blue subpixels of the organic light emitting display device, and are then cured by light to form the red, green, and blue color filters. Thus, the thin film encapsulation structure embedded with the color filters is obtained. Therefore, photolithography employing three photomasks, which must be used in a manufacturing process of a conventional color filter layer, is effectively simplified, and damage caused by the manufacturing process to functional layers in organic light emitting diode (OLED) panels is reduced. Furthermore, by coating black polyimide (PI) on the second encapsulation layer (SiN) to form the light shielding layer, and exposing the red, green, and blue subpixels by photolithography, the bending endurance of the light shading layer is enhanced.

### BRIEF DESCRIPTION OF DRAWINGS

The invention described herein is by way of example only, with reference to the accompanying drawings:

FIG. 1 is a schematic cross-sectional view of an existing organic light emitting display device having a polarizer.

FIG. 2 is a schematic cross-sectional view of an existing organic light emitting display device having a color filter layer.

FIG. 3 is a flow chart of a method for manufacturing an encapsulation structure of an organic light emitting display device in accordance with an embodiment of the present disclosure;

FIG. 4 is a schematic lateral view showing steps S10 and S20 in the method for manufacturing the encapsulation structure of the organic light emitting display device in accordance with an embodiment of the present disclosure.

FIG. 5 is a schematic lateral view showing steps S30 and S40 in the method for manufacturing the encapsulation structure of the organic light emitting display device in accordance with an embodiment of the present disclosure.

FIG. 6 is a schematic lateral view showing steps S50 and S60 in the method for manufacturing the encapsulation structure of the organic light emitting display device in accordance with an embodiment of the present disclosure.

FIG. 7 is a schematic lateral view showing steps S70 and S80 in the method for manufacturing the encapsulation structure of the organic light emitting display device in accordance with an embodiment of the present disclosure, and is also used as a schematic cross-sectional view of the encapsulation structure and the organic light emitting display device manufactured based upon the method.

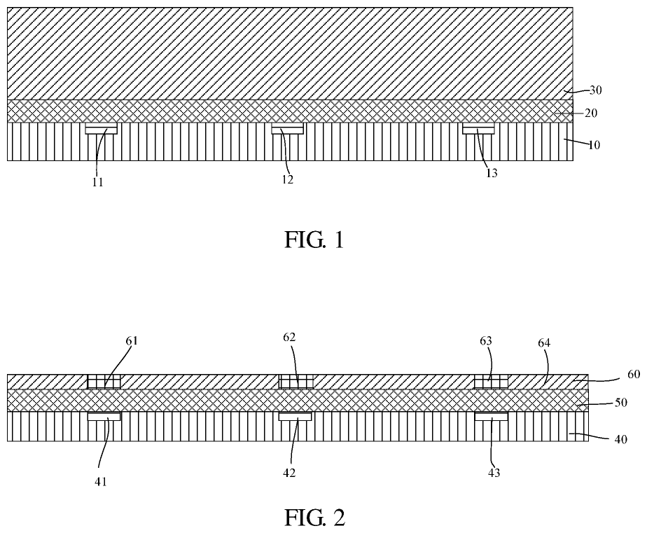

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure. In the drawings, units with similar structures are indicated by the same reference number.

### First Embodiment

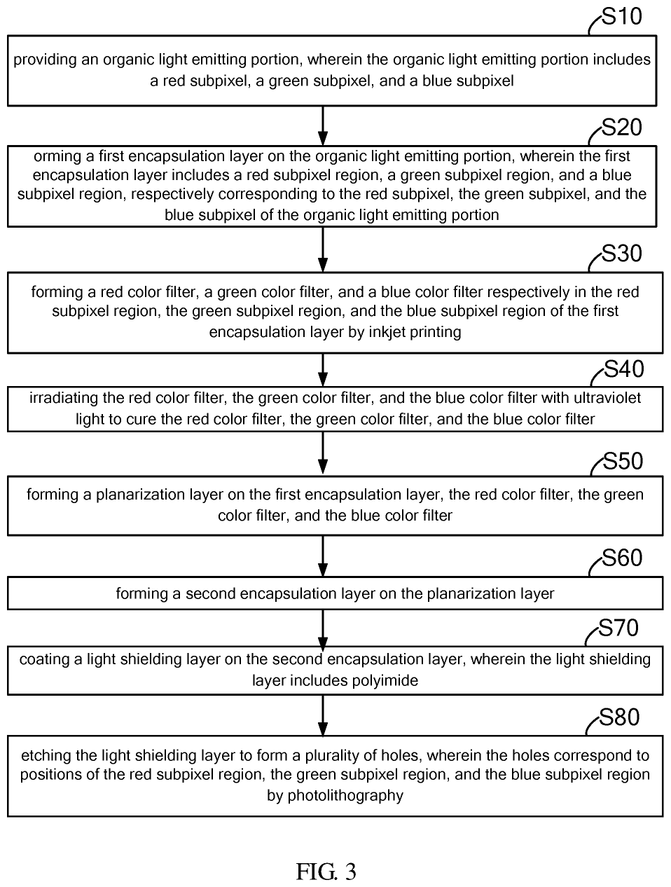

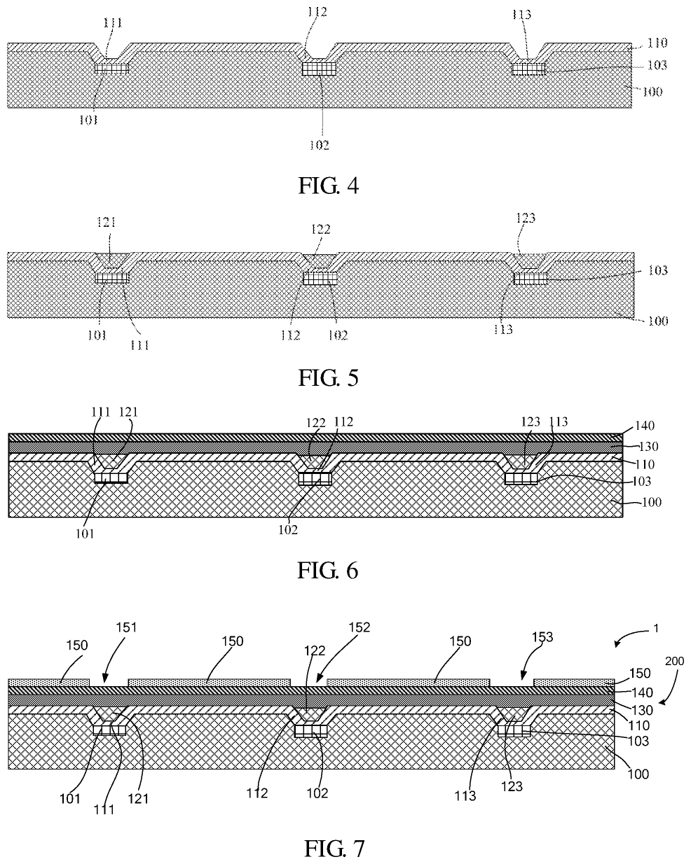

Referring to FIG. 3, which is a flow chart of a method for manufacturing an encapsulation structure of an organic light emitting display device in accordance with an embodiment of the present disclosure. Referring to FIG. 4 to FIG. 7, which are schematic lateral views showing steps S10 and S80 in the method for manufacturing the encapsulation structure of the organic light emitting display device in accordance with an embodiment of the present disclosure.

The present disclosure provides a method for manufacturing an encapsulation structure of an organic light emitting display device 1. The method includes the following steps:

As shown in FIG. 4, in step S10, an organic light emitting portion 100 is provided, wherein the organic light emitting portion includes red subpixels 101, green subpixels 102, and blue subpixels 103.

As shown in FIG. 4, in step S20, a first encapsulation layer 110 is formed on the organic light emitting portion 100, wherein the first encapsulation layer includes red subpixel regions 111, green subpixel regions 112, and blue subpixel regions 113, respectively corresponding to the red subpixels 101, the green subpixels 102, and the blue subpixels 103 of the organic light emitting portion 100. In accordance with a preferred embodiment of the present disclosure, material of the first encapsulation layer 110 is silicon nitride (Si₃N₄), and the first encapsulation layer 110 is formed on the organic light emitting portion 100 by plasma enhanced chemical vapor deposition (PECVD).

As shown in FIG. 5, in step S30, red color filters 121, green color filters 122, and blue color filters 123 are respectively formed in the red subpixel regions 111, the green subpixel regions 112, and the blue subpixel regions 113 of the first encapsulation layer by inkjet printing (IJP). In accordance with a preferred embodiment of the present disclosure, by the inkjet printing, materials containing red color resists, green color resists, and blue color resists precisely cover the red subpixel regions 111, the green subpixel regions 112, and the blue subpixel regions 113.

As shown in FIG. 5, in step S40, the red color filters 121, the color filters 122, and the blue color filters 123 are cured by ultraviolet light irradiation.

As shown in FIG. 6, in step S50, a planarization layer 130 is formed on the first encapsulation layer 110, the red color filters 121, the green color filters 122, and the blue color filters 123. In accordance with a preferred embodiment of the present disclosure, a transparent planarization layer 130 is formed on the first encapsulation layer 110, the red color filters 121, the green color filters 122, and the blue color filters 123 by inkjet printing.

As shown in FIG. 6, in step S60, a second encapsulation layer 140 is formed on the planarization layer 130. In accordance with a preferred embodiment of the present disclosure, material of the second encapsulation layer 140 is silicon nitride (Si₃N₄), and the second encapsulation layer 140 is formed on the planarization layer 130 by plasma enhanced chemical vapor deposition (PECVD).

As shown in FIG. 7, in step S70, a light shielding layer 150 is coated on the second encapsulation layer 140, wherein the light shielding layer includes black polyimide (black PI).

As shown in FIG. 7, in step S80, the light shielding layer 150 is etched to form a plurality of holes 151, 152, 153, wherein the holes correspond to positions of the red subpixel regions 111, the green subpixel regions 112, and the blue subpixel regions 113 by photolithography. The holes 151, 152, 153 respectively serve as light output holes for the red subpixels 101, the green subpixels 102, and the blue subpixels 103, and the light shielding layer 150 formed of black polyimide absorbs external light and reduces reflection. In the present disclosure, black polyimide is used as material of the light shielding layer 150, has excellent mechanical properties, and can improve the bending endurance of the light shielding layer 150 in the art.

### Second Embodiment

Referring to FIG. 7, which is a schematic cross-sectional view of an organic light emitting display device manufactured based upon the above method in accordance with an embodiment of the present disclosure.

The present disclosure also provides an organic light emitting display device 1. An encapsulation structure of the organic light emitting display device 1 is formed by the above method, and the organic light emitting display device 1 includes an organic light emitting portion 100 and the encapsulation structure 200.

The organic light emitting portion 100 includes red subpixels 101, green subpixels 102, and blue subpixels 103.

The encapsulation structure 200 is disposed to cover the organic light emitting portion 100, and includes a first encapsulation layer 110, red color filters 121, green color filters 122, blue color filters 123, a planarization layer 130, a second encapsulation layer 140, and a light shielding layer 150.

The first encapsulation layer 110 is disposed on the organic light emitting portion 100, and includes red subpixel regions 111, green subpixel regions 112, and blue subpixel regions 113, respectively corresponding to the red subpixels 101, the green subpixels 102, and the blue subpixels 103 of the organic light emitting portion. In accordance with a preferred embodiment of the present disclosure, material of the first encapsulation layer 110 is silicon nitride (Si₃N₄), and the first encapsulation layer 110 is formed on the organic light emitting portion 100 by plasma enhanced chemical vapor deposition (PECVD).

The red color filters 121, the green color filters 122, and the blue color filters 123 are respectively formed in the red subpixel regions 111, the green subpixel regions 112, and the blue subpixel regions 113 of the first encapsulation layer. In accordance with a preferred embodiment of the present disclosure, by the inkjet printing (IJP), materials containing red color resists, green color resists, and blue color resists precisely cover the red subpixel regions 111, the green subpixel regions 112, and the blue subpixel regions 113 to form the red color filters 121, the green color filters 122, and the blue color filters 123. The red color filters 121, the color filters 122, and the blue color filters 123 are cured by ultraviolet light irradiation.

The planarization layer 130 is disposed on the first encapsulation layer 110, the red color filters 121, the green color filters 122, and the blue color filters 123. In accordance with a preferred embodiment of the present disclosure, a transparent planarization layer 130 is formed on the first encapsulation layer 110, the red color filters 121, the green color filters 122, and the blue color filters 123 by inkjet printing.

The second encapsulation layer 140 is disposed on the planarization layer 130. In accordance with a preferred embodiment of the present disclosure, material of the second encapsulation layer 140 is silicon nitride (Si₃N₄), and the second encapsulation layer 140 is formed on the planarization layer 130 by plasma enhanced chemical vapor deposition (PECVD).

The light shielding layer 150 is disposed on the second encapsulation layer 140, wherein the light shielding layer 150 includes polyimide, and a plurality of holes 151, 152, 153 are defined on positions of the red subpixel regions 111, the green subpixel regions 112, and the blue subpixel regions 113 in the light shielding layer. In accordance with a preferred embodiment of the present disclosure, by photolithography, the light shielding layer 150 are etched to form the plurality of holes 151, 152, 153, wherein the holes 151, 152, 153 correspond to positions of the red subpixel regions 111, the green subpixel regions 112, and the blue subpixel regions 113. The holes 151, 152, 153 respectively serve as light output holes for the red subpixels 101, the green subpixels 102, and the blue subpixels 103, and the light shielding layer 150 formed of black polyimide absorbs external light and reduces reflection. In the present disclosure, black polyimide is used as material of the light shielding layer 150, has excellent mechanical properties, and can improve the bending endurance of the light shielding layer 150 in the art.

### Third Embodiment

Referring to FIG. 7, which is a schematic cross-sectional view of an encapsulation structure manufactured based upon the above method in accordance with an embodiment of the present disclosure.

The present disclosure also provides an encapsulation structure 200 for an organic light emitting display device 1. The organic light emitting display device 1 includes an organic light emitting portion 100 including red subpixels 101, green subpixels 102, and blue subpixels 103. The encapsulation structure 200 is formed by the above method, is disposed to cover the organic light emitting portion 100, and includes a first encapsulation layer 110, red color filters 121, green color filters 122, blue color filters 123, a planarization layer 130, a second encapsulation layer 140, and a light shielding layer 150.

The first encapsulation layer 110 is disposed on the organic light emitting portion 100, and includes red subpixel regions 111, green subpixel regions 112, and blue subpixel regions 113, respectively corresponding to the red subpixels 101, the green subpixels 102, and the blue subpixels 103 of the organic light emitting portion. In accordance with a preferred embodiment of the present disclosure, material of the first encapsulation layer 110 is silicon nitride (Si₃N₄), and the first encapsulation layer 110 is formed on the organic light emitting portion 100 by plasma enhanced chemical vapor deposition (PECVD).

The red color filters 121, the green color filters 122, and the blue color filters 123 are respectively formed in the red subpixel regions 111, the green subpixel regions 112, and the blue subpixel regions 113 of the first encapsulation layer. In accordance with a preferred embodiment of the present disclosure, by the inkjet printing (IJP), materials containing red color resists, green color resists, and blue color resists precisely cover the red subpixel regions 111, the green subpixel regions 112, and the blue subpixel regions 113 to form the red color filters 121, the green color filters 122, and the blue color filters 123. The red color filters 121, the color filters 122, and the blue color filters 123 are cured by ultraviolet light irradiation. The planarization layer 130 is disposed on the first encapsulation layer 110, the red color filters 121, the green color filters 122, and the blue color filters 123. In accordance with a preferred embodiment of the present disclosure, a transparent planarization layer 130 is formed on the first encapsulation layer 110, the red color filters 121, the green color filters 122, and the blue color filters 123 by inkjet printing. The second encapsulation layer 140 is disposed on the planarization layer 130. In accordance with a preferred embodiment of the present disclosure, material of the second encapsulation layer 140 is silicon nitride (Si₃N₄), and the second encapsulation layer 140 is formed on the planarization layer 130 by plasma enhanced chemical vapor deposition (PECVD).

The light shielding layer 150 is disposed on the second encapsulation layer 140, wherein the light shielding layer 150 includes polyimide, and a plurality of holes 151, 152, 153 are defined on positions of the red subpixel regions 111, the green subpixel regions 112, and the blue subpixel regions 113 in the light shielding layer. In accordance with a preferred embodiment of the present disclosure, by photolithography, the light shielding layer 150 are etched to form the plurality of holes 151, 152, 153, wherein the holes 151, 152, 153 correspond to positions of the red subpixel regions 111, the green subpixel regions 112, and the blue subpixel regions 113. The holes 151, 152, 153 respectively serve as light output holes for the red subpixels 101, the green subpixels 102, and the blue subpixels 103, and the light shielding layer 150 formed of black polyimide absorbs external light and reduces reflection. In the present disclosure, black polyimide is used as material of the light shielding layer 150, has excellent mechanical properties, and can improve the bending endurance of the light shielding layer 150 in the art.

In summary, in the method for manufacturing the encapsulation structure of the organic light emitting display device, and the encapsulation structure and the organic light emitting display device manufactured by the method of the present disclosure, using inkjet printing, red, green, and blue color resists precisely cover the red, green, and blue subpixels of the organic light emitting display device, and are then cured by light to form the red, green, and blue color filters. Thus, the thin film encapsulation structure embedded with the color filters is obtained. Therefore, photolithography employing three photomasks, which must be used in a manufacturing process of a conventional color filter layer, is effectively simplified, and damage caused by the manufacturing process to functional layers in organic light emitting diode (OLED) panels is reduced. Furthermore, by coating black polyimide (PI) on the second encapsulation layer (SiN) to form the light shielding layer, and exposing the red, green, and blue subpixels by photolithography, the bending endurance of the light shading layer is enhanced.

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

1. A method for manufacturing an encapsulation structure of an organic light emitting display device, comprising:
a step S10 of providing an organic light emitting portion, wherein the organic light emitting portion includes a red subpixel, a green subpixel, and a blue subpixel;
a step of S20 of forming a first encapsulation layer on the organic light emitting portion, wherein the first encapsulation layer includes a red subpixel region, a green subpixel region, and a blue subpixel region, respectively corresponding to the red subpixel, the green subpixel, and the blue subpixel of the organic light emitting portion;
a step S30 of forming a red color filter, a green color filter, and a blue color filter respectively in the red subpixel region, the green subpixel region, and the blue subpixel region of the first encapsulation layer by inkjet printing;
a step S40 of irradiating the red color filter, the green color filter, and the blue color filter with ultraviolet light to cure the red color filter, the green color filter, and the blue color filter;
a step S50 of forming a planarization layer on the first encapsulation layer, the red color filter, the green color filter, and the blue color filter;
a step S60 of forming a second encapsulation layer on the planarization layer;
a step S70 of coating a light shielding layer on the second encapsulation layer, wherein the light shielding layer includes polyimide; and
a step S80 of etching the light shielding layer to form a plurality of holes, wherein the holes correspond to positions of the red subpixel region, the green subpixel region, and the blue subpixel region by photolithography.

2. The manufacturing method as claimed in claim 1, wherein material of the first encapsulation layer and the second encapsulation layer is SiN.

3. The manufacturing method as claimed in claim 2, wherein
the step S20 includes a step of forming the first encapsulation layer on the organic light emitting portion by chemical vapor deposition; and
the step 60 includes a step of forming the second encapsulation layer on the planarization layer by chemical vapor deposition.

4. The manufacturing method as claimed in claim 1, wherein
the step S50 includes a step of forming a transparent planarization layer on the first encapsulation layer, the red color filter, the green color filter, and the blue color filter by inkjet printing.

5. An organic light emitting display device comprising:
an organic light emitting portion including a red subpixel, a green subpixel, and a blue subpixel;
an encapsulation structure disposed to cover the organic light emitting portion, and including:
a first encapsulation layer disposed on the organic light emitting portion, and including a red subpixel region, a green subpixel region, and a blue subpixel region, respectively corresponding to the red subpixel, the green subpixel, and the blue subpixel of the organic light emitting portion;
a red color filter, a green color filter, and a blue color filter respectively formed in the red subpixel region, the green subpixel region, and the blue subpixel region of the first encapsulation layer;
a planarization layer disposed on the first encapsulation layer, the red color filter, the green color filter, and the blue color filter;
a second encapsulation layer disposed on the planarization layer;
a light shielding layer disposed on the second encapsulation layer; wherein the light shielding layer includes a polyimide, and a plurality of holes are defined on positions of the red subpixel region, the green subpixel region, and the blue subpixel region in the light shielding layer.

6. The organic light emitting display device as claimed in claim 5, wherein material of the first encapsulation layer and the second encapsulation layer is SiN.

7. An encapsulation structure for an organic light emitting display device, wherein an organic light emitting portion of the organic light emitting display device includes a red subpixel, a green subpixel, and a blue subpixel, and the encapsulation structure comprises:
a first encapsulation layer disposed on the organic light emitting portion, and including a red subpixel region, a green subpixel region, and a blue subpixel region, respectively corresponding to the red subpixel, the green subpixel, and the blue subpixel of the organic light emitting portion;
a red color filter, a green color filter, and a blue color filter respectively formed in the red subpixel region, the green subpixel region, and the blue subpixel region of the first encapsulation layer;
a planarization layer disposed on the first encapsulation layer, the red color filter, the green color filter, and the blue color filter;
a second encapsulation layer disposed on the planarization layer;
a light shielding layer disposed on the second encapsulation layer; wherein the light shielding layer includes a polyimide, and a plurality of holes are defined on positions of the red subpixel region, the green subpixel region, and the blue subpixel region in the light shielding layer.

8. The encapsulation structure as claimed in claim 7, wherein material of the first encapsulation layer and the second encapsulation layer is SiN.

9.-11. (canceled)
